(19) United States
(12) Patent Application Publication
(10) Pub. No.: US 2024/0218547 A1
(43) Pub. Date: Jul. 4, 2024

(54) METAL STRUCTURE AND METHOD FOR MANUFACTURING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Tae Hwan SONG, Gyeonggi-do (KR)

(73) Assignee: POINT ENGINEERING CO., LTD., Chungcheongnam-do (KR)

(21) Appl. No.: 18/558,543

(22) PCT Filed: May 3, 2022
(86) PCT No.: PCT/KR2022/006360

§ 371 Date: Nov. 2, 2023

(30) Foreign Application Priority Data
May 7, 2021 (KR) 10-2021-0059345
May 17, 2021 (KR) 10-2021-0063670

(51) Int. Cl. C25D 1/10; C25D 5/10; C25D 5/48; G03F 1/50

(52) U.S. Cl. CPC C25D 1/10; C25D 5/10; C25D 5/48; G03F 1/50

(57) ABSTRACT

The present disclosure provides a metal structure made from an anodic oxide film and a method of manufacturing the same.

### BACKGROUND

### Technical Field

The present disclosure relates to a metal structure made from an anodic oxide film and a method of manufacturing the same.

### Description of Related Art

Regarding metal structures having micro-scale through holes, the micro-scale through holes can be formed by applying a laser beam or by using a mold and a plating process.

The through hole formation by laser beam application has the problem of increasing manufacturing costs with increase in the number of through holes. Additionally, there is a problem that it is difficult to form various shapes of through holes.

On the other hand, the method of using a mold and a plating process is advantageous in that the manufacturing cost does not increase proportionally with increase in the number of through holes and through holes having various forms can be formed. However, this method has a problem in terms of the thickness of the metal structure thus produced. More specifically, the mold is commonly made of photoresist, which is a photosensitive material. When the photoresist is applied form a thick single-layered film, it is difficult to form vertical through holes. Meanwhile, when the photoresist is applied to form a multilayered photoresist film, a thick mold can be produced, but this case poses a problem that steps occur between the layers.

Therefore, a new approach to form through holes in a metal structure is required.

### DOCUMENTS OF RELATED ART

### Patent Document

(Patent Document 1) Korean Patent Application Publication No. 10-2017-0068241

### SUMMARY

### Technical Problem

The present disclosure is made to solve the problems occurring in the related art and thus provides a metal structure made from an anodic oxide film and a method of manufacturing the same.

### Technical Solution

In order to solve and problems and accomplish the objective described above, in one aspect of the present disclosure, there is provided a method of manufacturing a metal structure, the method including: preparing an anodic oxide film; forming an anodic oxide film island by removing a peripheral portion of the an anodic oxide film; forming a metal body by forming a metal layer around the anodic oxide film island; and forming a through hole in the metal body by removing the anodic oxide film island.

The forming of the metal body may use a plating process.

The forming of the metal body may be a process of forming multiple types of metal layers stacked in order.

In another aspect of the present disclosure, there is provided a method of manufacturing a metal structure, the method including: preparing an an anodic oxide film; applying a photosensitive material on a surface of the anodic oxide film; forming a photosensitive material island by partially removing the applied photosensitive material specifically in a peripheral region; forming an anodic oxide film island by removing the anodic oxide film in the peripheral region but not removing the anodic oxide film disposed under the photosensitive material island; forming a metal body by forming a metal layer around the anodic oxide film island and the photosensitive material island; and forming a through hole in the metal body by removing the anodic oxide film island and the photosensitive material island.

Additionally, the photosensitive material is a negative photoresist.

In a further aspect of the present disclosure, there is provided a metal structure including: a metal body having a through hole; and a plurality of micro-trenches having a width and depth and formed on an inner wall of the through hole. The micro-trenches may extend in a thickness direction of the body, and the micro-trenches may be arranged in a circumferential direction of the through hole.

The width and depth of the micro-trench range from 20 nm to 1 μm.

The through hole includes a first through hole vertically extending in the thickness direction of the metal body and a second through hole provided on the first through hole and tapered to have a relatively wide upper portion and a relatively narrow lower portion.

The first through hole may be provided with the micro-trenches and the second through hole may not be provided with the micro-trenches.

The metal body may be a multilayered structure in which multiple types of metal layers are stacked in a thickness direction of the metal body.

The metal body includes a magnetic metal.

At least one of solid, liquid, and gas phases passes through the through hole.

The through hole may be filled with at least one of solid, liquid, and gas phases.

The metal structure may be a mask for deposition or a mask for light exposure.

The metal structure may be a mold.

The metal structure may further include a coating layer formed on at least a portion of the surface of the metal structure.

### Advantageous Effects

The present disclosure provides a metal structure made from an anodic oxide film and a method of manufacturing the same.

### BRIEF DESCRIPTION OF THE DRAWINGS

FIG. 1(a) is a plan view of a metal structure according to a first preferred embodiment of the present disclosure.

FIG. 1(b) is a cross-sectional view taken along line A-A′ of FIG. 1(a).

FIG. 1(c) is a view showing the inner wall surface of a through hole of FIG. 1.

FIGS. 2(a) through 5(b) are views illustrating a method of manufacturing the metal structure according to the first preferred embodiment of the present disclosure.

FIGS. 6(a) and 6(b) are views illustrating modifications to the metal structure according to the first preferred embodiment of the present disclosure.

FIG. 7(a) is a plan view of a metal structure according to a second preferred embodiment of the present disclosure.

FIG. 7(b) is a cross-sectional view taken along line A-A′ of FIG. 7(a).

FIG. 7(c) is a perspective view illustrating a cross sectional taken along line A-A′ of FIG. 7(a).

FIGS. 8(a) through 10(b) are views illustrating a method of manufacturing the metal structure according to the second preferred embodiment of the present disclosure.

FIGS. 11(a) and 11(b) are views illustrating modifications to the metal structure according to the second preferred embodiment of the present disclosure.

FIG. 12 is a diagram illustrating that a metal structure according to a preferred embodiment of the present disclosure is a mask for deposition of an organic material.

FIG. 13 is a diagram illustrating a metal structure with a coating layer on a surface thereof, according to a preferred embodiment of the present disclosure.

### DESCRIPTION OF THE EMBODIMENTS

The following merely illustrates the principles of the disclosure. Therefore, those skilled in the art will be able to implement the principles of the present disclosure and to make various devices that fall within the scope of the present disclosure with reference to the following description. It should be noted that all conditional terms and embodiments recited in this specification are intended to help understanding of the concept of the disclosure and are thus not to be construed to limit the disclosure to specific embodiments described herein.

The above objects, features, and advantages of the present disclosure will become more apparent from the following detailed description taken in conjunction with the accompanying drawings. With reference to the following detailed description and the accompanying drawings, the ordinarily skilled in the art may easily embody the technical concept of the disclosure.

In addition, the embodiments will be described herein with reference to cross-sectional views and/or plan views, which are ideal illustrations of the disclosure. In the drawings, the thicknesses of films and regions are exaggerated to effectively describe the technical concept. The form of the illustration may be modified depending on manufacturing technology and/or tolerance. Therefore, the embodiments of the disclosure are not limited to the specific forms illustrated but also include changes in the forms generated in the manufacturing process. The terminology used herein is for the purpose of describing particular embodiments only and is not intended to be limiting. As used herein, the singular forms “a”, “an”, and “the” are intended to include plural forms as well unless the context clearly indicates otherwise. It will be further understood that the terms “comprise”, “include”, or “have” when used in this specification specify the presence of stated features, regions, integers, steps, operations, elements and/or components, but do not preclude the presence or addition of one or more other features, regions, integers, steps, operations, elements, components and/or combinations thereof.

Hereinafter, preferred embodiments of the present disclosure will be described in detail with reference to the accompanying drawings. In describing various embodiments below, components that perform the same function will be given the same names and same reference numerals for convenience throughout all the embodiments. In addition, the configuration and operation already described in other embodiments will be omitted for convenience.

Hereinafter, first to second embodiments will be described separately, but embodiments that combine the components of each embodiment fall within the scope of the present disclosure.

### First Embodiment

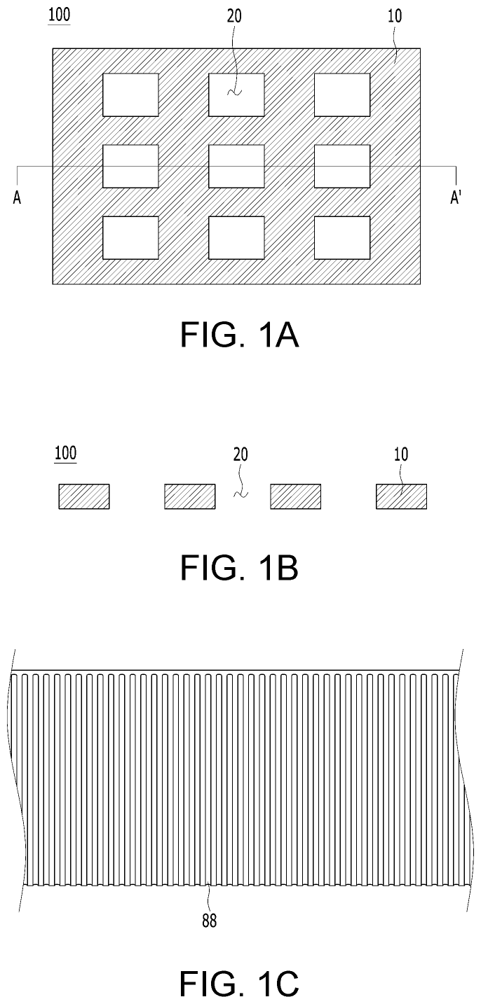

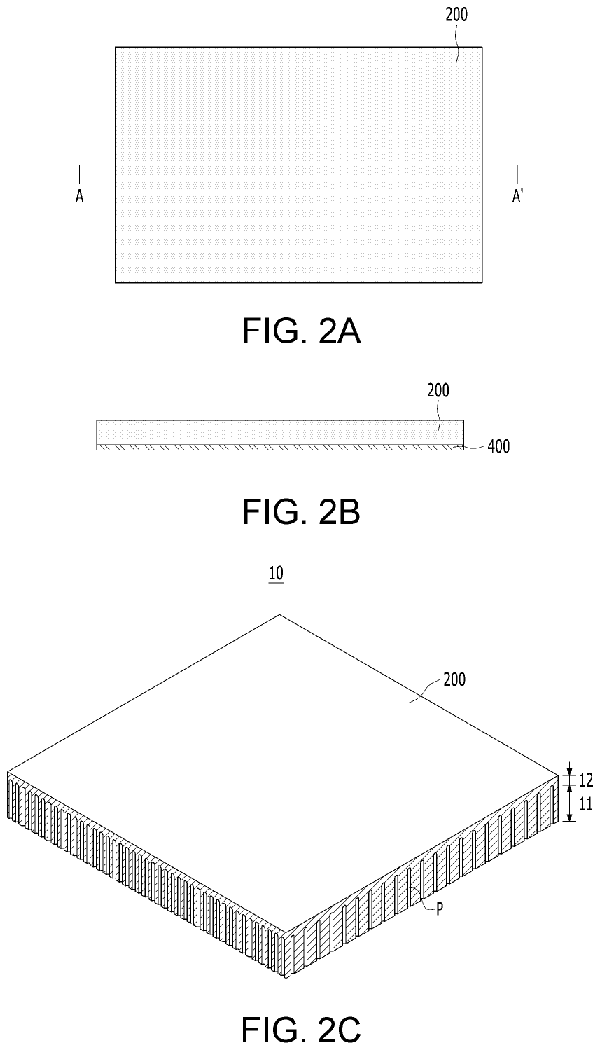

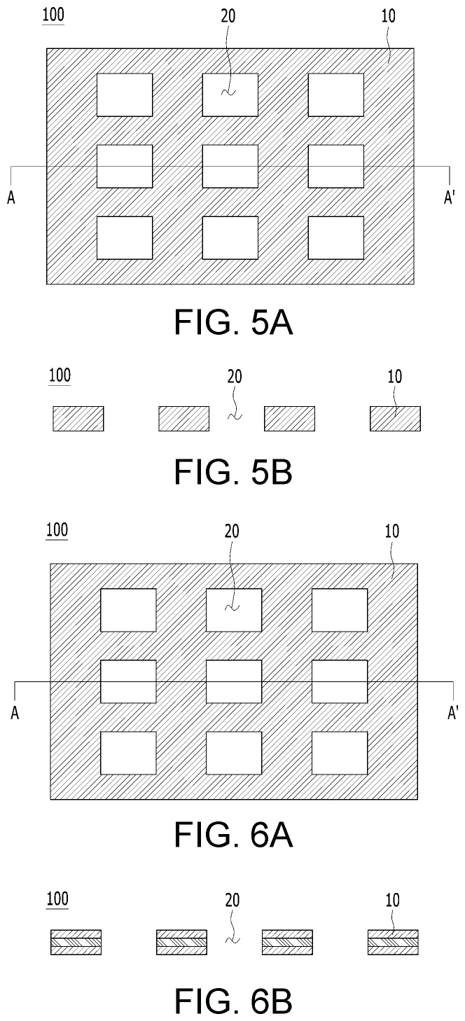

Hereinafter, a metal structure 100 according to a first preferred embodiment of the present disclosure will be described with reference to FIGS. 1(a) through 5(b). FIGS. 1(a) is a plan view of the metal structure 100 according to the first preferred embodiment of the present disclosure, FIG. 1(b) is a cross-sectional view taken along line A-A′ of FIG. 1(a), and FIG. 1(c) is a a view showing the inner wall surface of a through hole 20 of FIG. 1. FIGS. 2(a) to 5(b) are views showing a method of manufacturing the metal structure 100 according to the first preferred embodiment of the present disclosure.

Referring to FIGS. 1(a) through 1(c), the metal structure 100 according to the first preferred embodiment of the present disclosure includes a metal body 10 having through holes 20.

The inner wall of each of the through holes 20 is provided with a plurality of micro-trenches 88 having a width and depth.

Each of the micro-trenches 88 is formed in the inner wall of the through hole 20 in a manner to extend along the thickness direction of the metal body 10. The micro-trenches 88 are arranged in the circumferential direction of the through hole 20.

The micro-trenches 88 have a depth ranging from 20 nm to 1 μm and a width also ranging from 20 nm to 1 μm. Since the micro-trenches 88 are generated due to the pores p formed during the formation of the anodic oxide film 200, the width and depth of the micro-trenches 88 are equal to or smaller than the diameter of the pores p formed in the anodic oxide film 200. Meanwhile, in the process of forming the anodic oxide film islands 250 in the anodic oxide film 200, some of the pores p of the anodic oxide film 200 are crushed by an etching solution, so that some of the pores p formed during anodization are damaged. For this reason, at least some of the micro-trenches 88 may be formed with a depth larger than the diameter of the pores p.

The anodic oxide film 200 has numerous pores p. At least a portion of the anodic oxide film 200 is etched to form an internal space 210, and a metal filler is formed in the internal space 210 through electroplating. Therefore, the inner wall of the through hole 20 is provided with the micro-trenches 88 formed to communicate with the pores p of the anodic oxide film 200. The micro-trenches 88 as described above have the effect of increasing the surface area in the through hole 20.

The through hole 20 illustrated in the drawings has a square cross-sectional shape, but the cross-sectional shape is not limited to the illustrated form. The through hole 20 may have a circular cross-section or a polygonal cross-section other than a square cross-section.

Hereinafter, a metal structure 100 according to a first preferred embodiment of the present disclosure will be described. FIGS. 2(a) through 5(b) are views illustrating a method of manufacturing the metal structure according to the first preferred embodiment of the present disclosure.

Referring to FIGS. 2(a) to 2(c), a step of preparing the anodic oxide film 200 is performed.

The anodic oxide film 200 refers to a film formed by anodizing a metal as a base material and the pores 410 refer to holes formed when the metal is anodized to form the anodic oxide film 400. When aluminum (Al) or an aluminum alloy as a base metal is anodized, the anodic oxide film 200 made of anodic aluminum oxide (Al₂O₃) is formed on the surface of the base material. However, the base metal is not limited to the examples, and Ta, Nb, Ti, Zr, Hf, Zn, W, Sb, or any alloy thereof can be used as the base metal. The anodic oxide film 200 formed as described above is composed of a barrier layer 12 with no pores p formed therein and a porous layer 11 with pores formed therein. When the base material is removed from the structure in which the anodic oxide film 200 including the barrier layer 11 and the porous layer 12 is formed on the base material, only the anodic oxide film 200 made of anodic oxide aluminum (Al₂O₃) remains. In the anodic oxidation film 200, the pores p may be open holes extending from tom to bottom of the anodic oxidation film 200 in the case where the barrier layer 12 formed during anodic oxidation is completely removed. Alternatively, the pores p may be closed holes closed at the top or bottom end thereof in the case where the barrier layer 12 remains (see FIG. 2(c)).

The anodic oxide film has a thermal expansion coefficient of 2 to 3 ppm/° C. For this reason, when exposed to a high temperature environment, the anodic oxide film suffers less thermal deformation. Therefore, even though the manufacturing environment of the metal structure 100 is a high temperature environment, the metal structure can be used without thermal deformation.

A seed layer 400 is provided on the lower surface of the anodic oxide film 200. The seed layer 400 may be provided on the lower surface of the anodic oxide film 200 before the internal space 210 is formed in the anodic oxide film 200. Meanwhile, a support substrate (not shown) is formed under the anodic oxide film 200 for convenient handling of the anodic oxide film 200. In this case, the seed layer 400 may be formed on the upper surface of the support substrate, and the anodic oxide film 200 provided with the internal space 210 may be combined with the support substrate. The seed layer 400 may be made of copper (Cu) and may be formed by a deposition process.

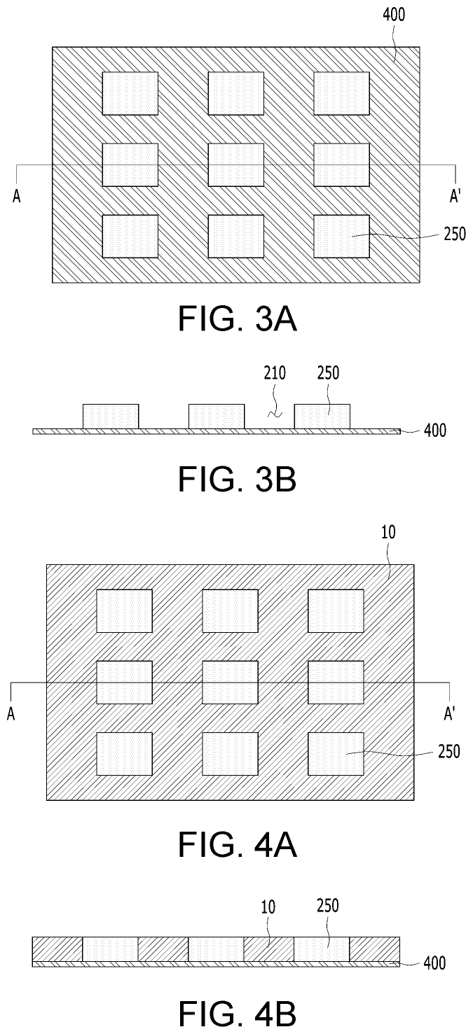

Next, referring to FIGS. 3(a) and 3(b), a step of removing the anodic oxide film 200 in a peripheral region to form an anodic oxide film island 250.

The internal space 210 is formed in the anodic oxide film 200. The internal space 210 may be formed by wet etching a portion of the anodic oxide film 200. To this end, a photo resist film is formed on the upper surface of the anodic oxide film 200 and patterned, and then the anodic oxide film 200 in the patterned opening reacts with an etching solution to form the internal space 210.

The anodic oxide film island 250 is formed by removing the anodic oxide film 200 in the peripheral area. Due to the configuration of the vertical pores p provided in the anodic oxide film 200, the side walls of the anodic oxide film island 250 have a vertical profile.

The sidewalls of the anodic oxide film islands 250 are provided with long concavo-convex portions extending along the longitudinal direction (top-to-bottom direction) of the anodic oxide film 200. Micro-trenches 88 are formed using the concavo-convex portions. The concavo-convex portions extend long in the top-to-bottom direction of the anodic oxide film 200, and is composed of a plurality of grooves spaced from each other in the sidewall. The concavo-convex portions include a pore-type concave-convex portion formed when the pores p formed during the formation of the anodic oxide film are opened by the etching process and an etched-type concavo-convex portion formed during etching of the anodic oxide film 200 formed to correspond to the concavo-convex pattern of the photoresist. Since the pore-type concave-convex portion is formed due to the pores p formed during the formation of the anodic oxide film 200, the width and depth of each groove constituting the pore-type concavo-convex portion ranges from 10 nm to 1 μm. The etched-type concavo-convex portion may be formed corresponding to the shape of the photoresist when the internal space 210 is formed by etching the anodic oxide film 200, regardless of the pores p. The anodic oxide film 200 reacts with the etching solution in the opening of the photoresist and is thus vertically etched conforming to the shape of the opening of the photoresist, thereby forming a durable space 40. At the time of patterning the photoresist, when the boundary of the opening of the photoresist is uneven, the side wall of the internal space 210 of the anodic oxide layer 200 is etched to be uneven when shown in a horizontally cross-sectioned view due to the uneven pattern boundary of the photoresist. Therefore, the concavo-convex portion on the side wall of the anodic oxide film island 250 becomes an etched uneven portion. A pore-type concavo-convex portion is formed on the wall of the etched-type concavo-convex portion. Since the concavo-convex portion is formed along the wall surface of the etched concave-convex portion, from a macroscopic perspective, the concavo-convex portion includes the pore-type concave-convex portion and the etched concave-convex portion. The width and depth of the groove constituting the etched-type concavo-convex portion are formed to be larger than the width and depth of the groove constituting the pore-type concavo-convex portion. Preferably, the width and depth of the groove constituting the etched-type concavo-convex portion are in the range of 100 nm or more and 30 μm or less.

Next, referring to FIGS. 4(a) and 4(b), a step of forming the metal body 10 by forming a metal layer around the anodic oxide film island 250 is performed.

The metal layer is formed in the internal spaces 210 through electroplating using a seed layer 400. The metal layer includes at least one selected from: copper (Cu), silver (Ag), gold (Au), nickel (Ni), rhodium (Rd), platinum (Pt), iron (Fe), iridium (Ir), palladium (Pd), cobalt (Co), alloys of the mentioned metals, palladium-cobalt (PdCo) alloy, palladium-nickel (PdNi) alloy or nickel-phosphorus (NiPh) alloy, nickel-manganese (NiMn) alloy; nickel-cobalt (NiCo) alloy, nickel-iron (NiFe) alloy, and nickel-tungsten (NiW) alloy. However, the metal constituting the metal layer is not limited to the examples, and any metal that can improve the physical, chemical and/or electrical properties of the metal structure 100 can be used. Additionally, when used as a mask for the metal structure 100, the metal layer may be made of invar.

When the plating process is completed, a planarization process may be performed. That is, a chemical mechanical polishing (CMP) process is formed to remove a portion of the metal layer protruding from the upper surface of the anodic oxide film 200 so that the metal layer is planarized.

Meanwhile, after the plating process is completed, the temperature is increased, and the metal layer is pressed to densify the metal layer. When the photoresist material is used as a mold, since the photoresist exists around the metal layer after the plating process is completed, the process of raising the temperature and applying the pressure to the metal layer cannot be performed. Alternatively, according to a preferred embodiment of the present disclosure, since the anodic oxide film island 250 is provided around the metal layer formed through the plating process, the metal layer exhibits little thermal deformation although the temperature is raised due to a low thermal expansion coefficient of the anodic oxide film. Therefore, a process of densifying the metal layer can be performed while minimizing the thermal deformation. Therefore, it is possible to obtain a denser metal layer than technology using a photoresist film as a mold.

Next, referring to FIGS. 4(a) and 4(b), a step of removing the anodic oxide film island 250 is performed to form the through holes 20 in the metal body 10.

The through holes 20 are formed by removing the anodic oxide film island 250.

The anodic oxide film island 250 can be removed using an etching solution that reacts only with the anodic oxide film 200. The inner wall of each of each through holes 20 is provided with a plurality of micro-trenches 88 having a width and a depth. Each of the micro-trenches 88 is formed in the inner wall of the through hole 20 in a manner to extend along the thickness direction of the metal body 10. The micro-trenches 88 are arranged in the circumferential direction of the through hole 20. The micro-trenches 88 have a depth ranging from 20 nm to 1 μm and a width also ranging from 20 nm to 1 μm. Since the micro-trenches 88 are generated due to the pores p formed during the formation of the anodic oxide film 200, the width and depth of the micro-trenches 88 are equal to or smaller than the diameter of the pores p formed in the anodic oxide film 200. Meanwhile, in the process of forming the anodic oxide film islands 250 in the anodic oxide film 200, some of the pores p of the anodic oxide film 200 are crushed by an etching solution, so that some of the pores p formed during anodization are damaged. For this reason, at least some of the micro-trenches 88 may be formed with a depth larger than the diameter of the pores p.

Next, the seed layer 400 is removed. The seed layer 400 may be removed at the final stage or after the plating process is completed.

Through the above-described processes, the metal structure 100 according to the first preferred embodiment of the present disclosure is manufactured.

FIGS. 6(a) and 6(b) are diagrams showing a modification to the metal structure 100 according to the first preferred embodiment of the present disclosure. FIG. 6(a) is a plan view of one modification to the metal structure 100 according to the first preferred embodiment of the present disclosure, and FIG. 6(b) is a cross-sectional view taken along line A-′A of FIG. 6(a).

In the case of this modification to the metal structure 100 according to the first preferred embodiment of the present disclosure, it differs from the metal structure according to the first preferred embodiment in that multiple metal layers made of different metals are stacked. In this modification to the metal structure 100 according to the first preferred embodiment of the present disclosure, the metal body 10 is formed by stacking a plurality of different metals in the thickness direction thereof. The metal layer includes at least one of copper (Cu), silver (Ag), gold (Au), nickel (Ni), rhodium (Rd), platinum (Pt), iron (Fe), iridium (Ir), palladium (Pd), cobalt (Co), alloys of the mentioned metals, palladium-cobalt (PdCo) alloy, palladium-nickel (PdNi) alloy or nickel-phosphorus (NiPh) alloy, nickel-manganese (NiMn) alloy, nickel-cobalt (NiCo) alloy, nickel-iron (NiFe) alloy, and nickel-tungsten (NiW) alloy. However, the metal constituting the metal layer is not limited to the examples. Aside from the examples, the metal may include a magnetic metal.

### Second Embodiment

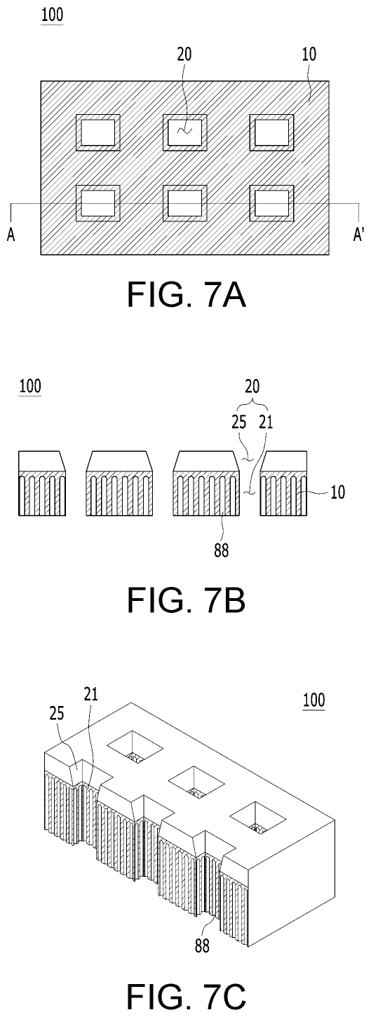

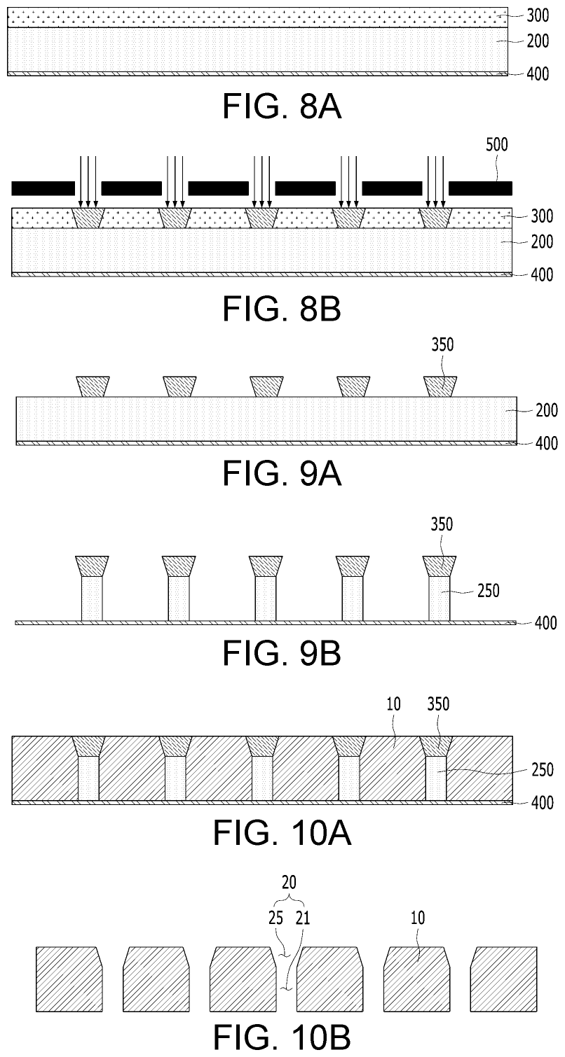

Hereinafter, a metal structure 100 according to a second preferred embodiment of the present disclosure will be described with reference to FIGS. 7(a) through 10(b). FIGS. 7(a) is a plan view of the metal structure 100 according to the second preferred embodiment of the present disclosure, FIG. 7(b) is a cross-sectional view taken along line A-A′ of FIG. 7(a), and FIG. 7(c) is a perspective view including a cross sectional taken along line A-A′ of FIG. 7(a). FIGS. 8(a) through 10(b) are views illustrating a method of manufacturing the metal structure 100 according to the second preferred embodiment of the present disclosure.

Referring to FIGS. 7(a) through 7(c), the metal structure 100 according to the second preferred embodiment of the present disclosure includes a metal body 10 having through holes 20. Each of the through holes 20 includes a first through hole 21 having a vertical profile extending along the thickness direction of the metal body and a second through hole 25 tapered to have a relatively wide upper portion and a relatively narrow lower portion. The second through hole 25 continuously extends from the first through hole 21.

The cross sectional shape of the first through hole 21 is vertical, and the second through hole 25 has a funnel shape so that the cross sectional area of the second through hole 25 decreases toward an inner portion from the entrance.

The first through hole 21 is provided with micro-trenches 88, but the second through hole 25 is not provided with micro-trenches 88.

Hereinafter, a method of manufacturing the metal structure 100 according to the second preferred embodiment of the present disclosure will be described. FIGS. 8(a) through 10(b) are views illustrating the method of manufacturing the metal structure 100 according to the second preferred embodiment of the present disclosure.

Referring to FIGS. 8(a), a step of preparing an anodic oxide film 200 and a step of applying a photosensitive material 300 are performed. Since the steps of preparing the anodic oxide film 200 is the same as those described in the first embodiment, a detailed description is omitted here.

A photosensitive material 300 is applied to the surface of the anodic oxide film 200. The photosensitive material 300 may be a photoresist and preferably may be a negative photoresist.

Next, referring to FIGS. 8(b) and 9(a), a step of removing a portion of the photosensitive material 300 is performed to form photosensitive material islands 350. First, referring to FIG. 8(b), the photosensitive material 300 is exposed to light while using a mask 500. The photosensitive material may be a negative photoresist that undergoes a chemical reaction when exposed, thereby enhancing polymer bonds. Through this, it is possible to form second through holes 25 having a relatively wide upper portion and a relatively narrow lower portion thereof. After the exposure process, development is performed to form photosensitive material islands 350 on the upper surface of the anodic oxide film 200, as shown in FIG. 9(a). The photosensitive material islands 350 are formed by removing the photosensitive material 300 around the periphery thereof. The photosensitive material islands 350 are formed such that the width gradually increases toward the top from the bottom.

Next, referring to FIG. 9(b), the anodic oxide film 200 in the peripheral region is removed but the anodic oxide film island disposed under the photosensitive material islands 350 is not removed, so that anodic oxide film islands 250 are formed.

An etching solution supplied to the open area around the photosensitive material islands 350 disposed on the upper surface of the anodic oxide film 200 reacts with the anodic oxide film 200, thereby removing the anodic oxide film 200 formed in the open area. Thus, the anodic oxide film islands 250 are formed.

The photosensitive material islands 350 are provided on the upper surface of the anodic oxide islands 250, and internal spaces 210 are formed around the anodic oxide islands 250 and the photosensitive material islands 350.

The sidewalls of the anodic oxide film islands 250 are provided with long concavo-convex portions extending along the longitudinal direction (top-to-bottom direction) of the anodic oxide film 200. Micro-trenches 88 are formed using the concavo-convex portions. The concavo-convex portions extend long in the top-to-bottom direction of the anodic oxide film 200, and is composed of a plurality of grooves spaced from each other in the sidewall. The concavo-convex portion is formed as pores p that are formed during the formation of the anodic oxide film is opened during the etching process.

Unlike the side walls of the anodic oxide islands 250, the side walls of the photosensitive material islands 350 are not provided with concavo-convex portions.

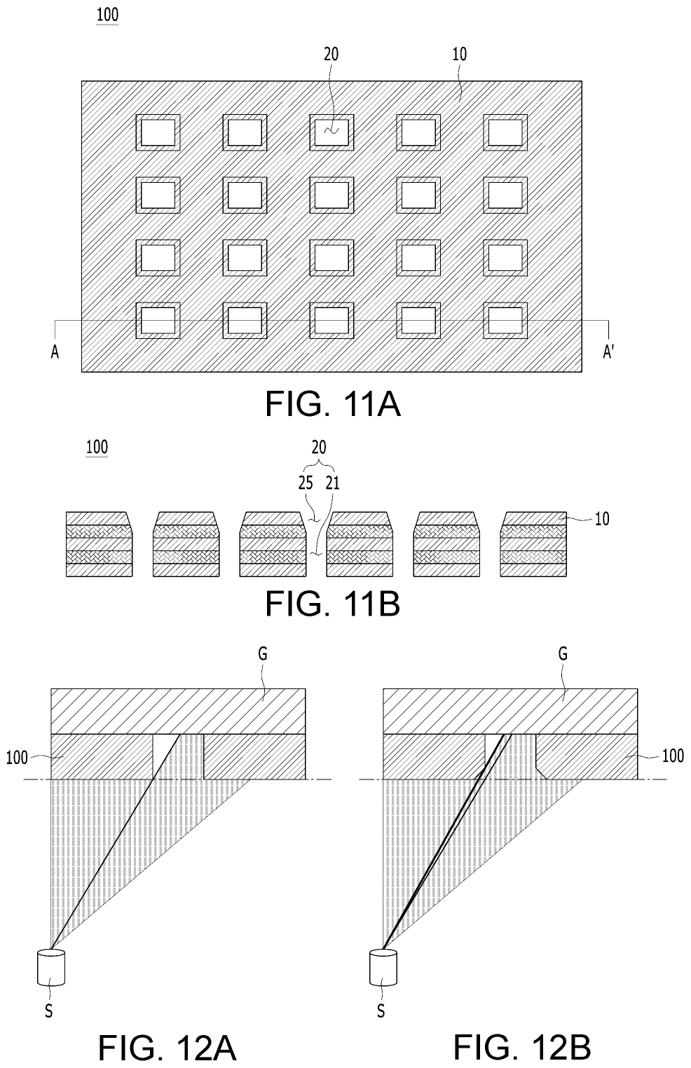

Next, referring to FIG. 10(a), a step of forming a metal layer around the anodic oxide film islands 250 and the photosensitive material islands 350 is performed to form a metal body 10.

The metal layer is formed in the internal spaces 210 through electroplating using a seed layer 400. The metal layer includes at least one selected from: copper (Cu), silver (Ag), gold (Au), nickel (Ni), rhodium (Rd), platinum (Pt), iron (Fe), iridium (Ir), palladium (Pd), and cobalt (Co); alloys of the mentioned metals; palladium-cobalt (PdCo) alloy; palladium-nickel (PdNi) alloy or nickel-phosphorus (NiPh) alloy; nickel-manganese (NiMn) alloy; nickel-cobalt (NiCo) alloy; nickel-iron (NiFe) alloy; and nickel-tungsten (NiW) alloy. However, the metal constituting the metal layer is not limited to the examples, and any metal that can improve the physical, chemical and/or electrical properties of the metal structure 100 can be used. Additionally, when used as a mask for the metal structure 100, the metal layer may be made of invar.

When the plating process is completed, a planarization process may be performed. That is, a chemical mechanical polishing (CMP) process is formed to remove a portion of the metal layer protruding from the upper surface of the anodic oxide film 200 so that the metal layer is planarized.

Next, referring to FIG. 10(b), a step of removing the anodic oxide film islands 250 and the photosensitive material islands 350 is performed to form through holes 20 in the metal body 10.

The through holes 20 are formed by removing the anodic oxide film islands 250 and the photosensitive material islands 350.

The anodic oxide film islands 250 are removed to form the first through holes 21 and the photosensitive material islands 350 are removed to form the second through holes 25. The cross sectional shape of the first through hole 21 is vertical, and the second through hole 25 has a tapered shape so that the inner dimension increases toward the upper end. The second through hole 25 is tapered toward the first through hole 21.

Next, the seed layer 400 is removed. The seed layer 400 may be removed at the final stage or after the plating process is completed.

Through the above-described processes, the metal structure 100 according to the second preferred embodiment of the present disclosure is manufactured.

FIGS. 11(a) and 11(b) are diagrams illustrating a modification to the metal structure 100 according to the second preferred embodiment of the present disclosure. FIG. 11(a) is a plan view of one modification to the metal structure 100 according to the second preferred embodiment of the present disclosure, and FIG. 11(b) is a cross-sectional view taken along line A-′A of FIG. 11(a).

In the case of this modification to the metal structure 100 according to it is differs from the metal structure 100 according to the second preferred embodiment of the present disclosure in that multiple metal layers made of different metals are stacked. In this modification to the metal structure 100 according to the first preferred embodiment of the present disclosure, the metal body 10 is formed by stacking a plurality of different metals in the thickness direction thereof. The metal layer includes at least one selected from: copper (Cu), silver (Ag), gold (Au), nickel (Ni), rhodium (Rd), platinum (Pt), iron (Fe), iridium (Ir), palladium (Pd), and cobalt (Co); alloys of the mentioned metals; palladium-cobalt (PdCo) alloy; palladium-nickel (PdNi) alloy or nickel-phosphorus (NiPh) alloy; nickel-manganese (NiMn) alloy; nickel-cobalt (NiCo) alloy; nickel-iron (NiFe) alloy; and nickel-tungsten (NiW) alloy. However, the metal constituting the metal layer is not limited to the examples. Aside from the examples, the metal may include a magnetic metal.

At least one of solid, liquid, and gas phases may pass through the through holes 20 of the metal structure 100. The through holes 20 provided in the metal structure 100 may function as passages through which at least one of solid, liquid, and gas phases passes. In this case, the direction of the micro-trenches 88 provided on the inner walls of the through holes 20 and the direction of flow of the material passing through the through holes 20 are the same, so the material can more easily pass through the through hole 20.

The through holes 20 may be filled with at least one of solid, liquid, and gas phases. The through holes 20 provided in the metal structure 100 may function as passages through which at least one of solid, liquid, and gas phases passes. In this case, due to the configuration of the micro-trenches 88 provided in the inner wall of the through hole 20, the contact surface area of the material filling the through hole 20 increases, so that the bonding strength is increased.

Alternatively, the metal structure 100 may be a mold. In this case, the through hole 20 provided in the metal structure 100 is a space whose shape corresponds to the shape of the end product to be manufactured. The inside of the through hole 20 can be filled with a material, and the material is then solidified.

The metal structure may serve as a mask for deposition or a mask for light exposure. In this case, due to the configuration of the micro-trenches 88 provided in the inner wall of the through hole 20, heat dissipation of the metal structure 100 can be more effectively achieved, so that thermal deformation can be reduced.

FIG. 12 is a diagram showing a case where the metal structure 100 serves, for example, as a deposition mask. FIG. 12(a) illustrates a case where the metal structure 100 according to the first preferred embodiment of the present disclosure is used as a deposition mask, and FIG. 12(b) illustrates a case where the metal structure 100 according to the second preferred embodiment of the present disclosure is used as a deposition mask.

The metal structure 100 is provided between a deposition source S and a target substrate G such as a glass substrate, and an organic material may be deposited on the target substrate G, such as a glass substrate, to form pixels.

The metal structure 100 according to the second embodiment has second through holes 25 whose upper portion is relatively wide and lower portion is relatively narrow. Thus, the metal structure 100 according to the second preferred embodiment can prevent ununiform deposition attributed to a shadow effect compared to the metal structure 100 according to the first preferred embodiment. The metal structure 100 according to the second embodiment has through holes 20 having a relatively wide entrance compared to the metal structure 100 according to the first embodiment, so that the shadow effect can be reduced.

The first through holes 21 of the through holes 20 may have an internal width in the range of from 10 μm to 15 μm, and the second through holes 25 may have an entrance width in the range of from 15 μm to 20 μm. Additionally, the thickness of the metal body 10 may in the range of from 30 μm to 40 μm.

In a preferred embodiment of the present disclosure, since the metal structure 1000 is manufactured using the anodic oxide film 200, the metal structure can be formed to have a small thickness which can further reduce the shadow effect.

In addition, since the metal body 10 is formed using a plating process, it can be formed by stacking a plurality of metal layers made of different metals, in which the content of each metal, the number of metal layers, etc. can be adjusted.

Meanwhile, in the metal structure 100 according to a preferred embodiment of the present disclosure, the metal body 10 includes a magnetic metal, so that the metal structure 100 can be attached to and detached from a target substrate (G) such as a glass substrate via the magnetic metal.

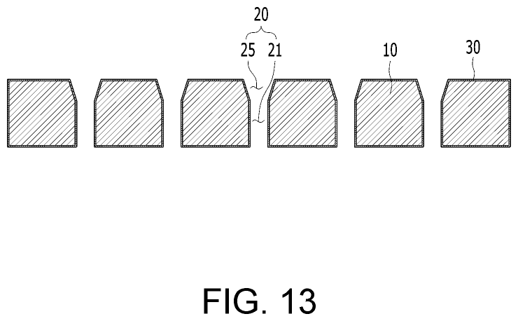

The metal structures 100 according to the first and second preferred embodiments of the present disclosure described above may further include a coating layer 30 provided on at least a portion of the surface thereof. FIG. 13 is a diagram illustrating a metal structure 100 provided with a coating layer 30 on the surface thereof.

The coating layer 30 may be formed on the entire surface of the metal structure 100 or may be formed only on a portion of the surface of the metal structure 100. In the case where the coating layer 30 is formed on a portion of the exposed surface of the metal structure 100, the coating layer is preferably formed on at least the inner wall surface of each of the through holes 20. The coating layer 30 provided on the inner wall surface of the through holes 20 functions to protect the inner wall surface of the through holes 20.

The coating layer 30 may be formed by alternately supplying a precursor gas and a reactant gas. In this case, the composition of the coating layer 30 may vary depending on the composition of the precursor gas and the reactant gas.

For example, the coating layer 30 may be formed by alternately supplying a precursor gas that is at least one of aluminum, silicon, hafnium, zirconium, yttrium, erbium, titanium, and tantalum and a reactant gas that can form the coating layer 30.

The coating layer 30 formed by alternately supplying a precursor gas and a reactant gas includes at least one selected from an aluminum oxide layer, a yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer, depending on the composition of each of the precursor gas and the reactant gas.

More specifically, when the coating layer 30 is made of an aluminum oxide layer, the precursor gas may include at least one selected from aluminum alkoxide (Al(T-OC₄H₉)₃), aluminum chloride (AlCl₃), trimethyl aluminum (TMA: Al(CH₃)₃), diethylaluminum ethoxide, tris(ethylmethylamido)aluminum, aluminum sec-butoxide, aluminum tri-bromide, aluminum tri-chloride, triethylaluminum, triisobutylaluminum, trimethylaluminum, and tris(diethylamido)aluminum.

When at least one of aluminum alkoxide (Al(T-OC₄H₉)₃), diethylaluminum ethoxide, tris(ethylmethylamido)aluminum, aluminum sec-butoxide, aluminum tri-bromide, aluminum tri-chloride, triethylaluminum, triisobutylaluminum, trimethylaluminum, and tris(diethylamido)aluminum is used as the precursor gas, H₂O may be used as the reactant gas.

When aluminum chloride (AlCl₃) is used as the precursor gas, O₃ may be used as the reactant gas.

When trimethyl aluminum (TMA: Al(CH₃)₃) is used as the precursor gas, O₃ or H₂O may be used as the reactant gas.

When the coating layer 30 is made of a yttrium oxide layer, the precursor gas may include at least one of yttrium chloride (YCl₃), Y(C₅H₅)₃, tris(N,N-bis(trimethylsilyl)amide)yttrium(III), yttrium(III) butoxide, tris(cyclopentadienyl)yttrium(III), tris(butylcyclopentadienyl)yttrium(III), tris(2,2,6,6-tetramethyl-3,5-heptandionato)yttrium(III), tris(cyclopentadienyl)yttrium (Cp₃Y), tris(methylcyclopentadienyl)yttrium ((CpMe)₃Y), tris(butylcyclopentadienyl)yttrium, and tris(ethylcyclopentadienyl)yttrium.

When aluminum chloride (AlCl₃) is used as the precursor gas, O₃ may be used as the reactant gas.

When at least one of tris(N,N-bis(trimethylsilyl)amide)yttrium(III), yttrium(III)butoxide, tris(cyclopentadienyl)yttrium(III), tris(butylcyclopentadienyl)yttrium(III), Tris(2,2,6,6-tetramethyl-3,5-heptandionato)yttrium(III), tris(cyclopentadienyl)yttrium(Cp₃Y), tris(methylcyclopentadienyl)yttrium((CpMe)₃Y), tris(butylcyclopentadienyl)yttrium, and tris(ethylcyclopentadienyl)yttrium is used as the precursor gas, at least one of H₂O, O₂, or O₃ may be used as the reactant gas.

When the coating layer 30 is made of a hafnium oxide layer, the precursor gas may include at least one of hafnium chloride (HfCl₄), Hf(N(CH₃)(C₂H₅))₄, Hf(N(C₂H₅)₂)₄, tetra(ethylmethylamido)hafnium, and pentakis(dimethylamido)tantalum.

In this case, when at least one of hafnium chloride (HfCl₄), Hf(N(CH₃)(C₂H₅))₄, and Hf(N(C₂H₅)₂)₄ is used as the precursor gas, O₃ may be utilized as the reactant gas.

When at least one of tetra(ethylmethylamido)hafnium and pentakis(dimethylamido)tantalum is used as the precursor gas, at least one of H₂O, O₂, or O₃ may be used as the reactant gas.

When the coating layer 30 is made of a silicon oxide layer, the precursor gas may include Si(OC₂H₅)₄. In this case, O₃ may be used as the reactant gas.

When the coating layer 30 is made of an erbium oxide layer, the precursor gas may include at least one of tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), tris(butylcyclopentadienyl)erbium(III), tris(2,2,6,6-tetramethyl-3,5-heptadienato)erbium (Er(thd)₃), Er(PrCp)₃, Er(CpMe)₂, Er(BuCp)₃, and Er(thd)₃.

In this case, at least one of tris-methylcyclopentadienyl erbium(III) (Er(MeCp)₃), erbium boranamide (Er(BA)₃), Er(TMHD)₃, and erbium(III)tris(2,2,6,6-tetramethyl-3,5-heptandionate), and tris(butylcyclopentadienyl)erbium(III) is used as the precursor gas, at lease one of H₂O, O₂, or O₃ may be used as the reactant gas.

When at least one of tris(2,2,6,6-tetramethyl-3,5-heptanedionato) erbium (Er(thd)₃), Er(PrCp)₃, Er(CpMe)₂, and Er(BuCp)₃ is used as the precursor gas, O₃ may be used as the reactant gas.

When Er(thd)₃ is used the precursor gas, O-radicals may be used as the reactant gas.

When the coating layer 30 is made of zirconium oxide, the precursor gas may include at least one of zirconium tetrachloride (ZrCl₄), Zr(T-OC₄H₉)₄, zirconium (IV) bromide, tetrakis(diethylamido)zirconium (IV), tetrakis(dimethylamido)zirconium(IV), tetrakis(ethylmethylamido)zirconium(IV), tetrakis(N,N′-dimethyl-formamidinate)zirconium, tetra(ethylmethylamido)hafnium, pentakis(dimethylamido)tantalum, tris(dimethylamino)(cyclopentadienyl)zirconium, and tris(2,2,6,6-tetramethyl-heptane-3,5-ionate)erbium.

When at least one of those described above is used as the precursor gas, at least one of H₂O, O₂, O₃, or O-radial may be used as the reactant gas.

When the coating layer 30 is made of a silicon oxide layer, the precursor gas may include Si(OC₂H₅)₄. In this case, at least one of H₂O, O₂, or O₃ may be used as the reactant gas.

When the coating layer 30 is composed of a transition metal layer, the precursor gas may include at least one of tantalum chloride (TaCl₅) and titanium tetrachloride (TiCl₄). In this case, H-radicals may be used as the reactant gas.

Specifically, when tantalum chloride (TaCl₅) is used as the precursor gas and H-radical is used as the reactant gas, the transition metal layer may be composed of a tantalum layer.

Alternatively, when titanium tetrachloride (TiCl₄) is used as the precursor gas and H-radical is used as the reactant gas, the transition metal layer may be composed of a titanium layer.

When the coating layer 30 is composed of a titanium nitride layer, the precursor gas may include at least one of bis(diethylamido)bis(dimethylamido)titanium(IV), tetrakis(diethylamido)titanium(IV), tetrakis(dimethylamido)titanium(IV), tetrakis(ethylmethylamido)titanium(IV), titanium(IV) bromide, titanium(IV) chloride, and titanium(IV) tertiary-butoxide. In this case, at least one of H₂O, O₂, O₃, or O-radial may be used as the reactant gas.

When the coating layer 30 is composed of a tantalum nitride layer, the precursor gas may include at least one of pentakis(dimethylamido)tantalum(V), tantalum(V) chloride, tantalum(V) ethoxide, and tris(diethylamino)(tert-butylimino) tantalum(V), In this case, at least one of H₂O, O₂, O₃, or O-radial may be used as the reactant gas.

When the coating layer 30 is composed of a zirconium nitride layer, the precursor gas may include at least one of zirconium (IV) bromide, zirconium (IV) chloride, zirconium (IV) tert-butoxide, tetrakis(diethylamido) zirconium (IV)), tetrakis(dimethylamino) zirconium (IV), and tetrakis(ethylmethylamino) zirconium (IV). In this case, at least one of H₂O, O₂, O₃, or O-radiall may be used as the reactant gas.

As described above, the composition of the coating layer 30 may vary depending on the precursor gas and the reactant gas.

The coating layer 30 may be formed by repeatedly performing a cycle of causing the precursor gas to be adsorbed on the surface of the metal body 10 and supplying the reactant gas to generate a monoatomic layer by chemical substitution reaction of the precursor gas and the reactant gas. Herein, the cycle will be referred to as “monoatomic layer creation cycle”.

When performing one monoatomic layer creation cycle, a thin monoatomic layer may be formed on the surface of the body 10. By repeatedly performing the monoatomic layer creation cycle, multiple monoatomic layers can be formed. More specifically, multiple monoatomic layers are formed by performing the monoatomic layer creation cycle in which a precursor gas adsorption step of causing the precursor gas to be adsorbed on the surface of the body 10, as carrier gas supply step, a reactant gas adsorption and substitution step, and a carrier gas supply step are sequentially performed. Thus, the coating layer 30 is formed.

In the precursor gas adsorption step, a process of forming a precursor adsorption layer may be performed by supplying the precursor gas using a precursor gas supply unit, so that the precursor gas can be adsorbed on the surface of the body 10. The precursor adsorption layer is formed as only one layer by a self-limiting reaction. Next, the carrier gas supply step may be performed using a carrier gas supply unit. In the carrier gas supply step, a process of removing excess precursor from the precursor adsorption layer is performed by supplying a carrier gas. In this case, an exhaust system may work together. The carrier gas can remove excess precursor remaining in the precursor adsorption layer, which is composed of only one layer formed through a self-limiting reaction. Then, the reactant gas adsorption and substitution step can be performed using a reactant supply unit. In the reactant adsorption and substitution step, the reactant gas is supplied to the surface of the precursor adsorption layer so that the reactant gas can be adsorbed on the surface of the precursor adsorption layer, and a monoatomic layer is created by chemical substitution of the precursor adsorption layer and the reactant gas. Next, a process of removing excess reactant gas is performed by performing the carrier gas supply step.

A step of repeatedly performing the monoatomic layer creation cycle is performed to create a plurality of monoatomic layers. Through this step, the coating layer 30 can be formed. This coating layer 30 provides improved corrosion resistance against corrosive gases and improves the rigidity of the metal structure 100.

Meanwhile, FIG. 13 illustrates the metal structure 100 according to the second embodiment in which the metal structure 100 has a coating layer 30 provided thereon. In a preferred embodiment of the present disclosure, the coating layer 30 is provided on the surface of the metal structure 100 according to the first embodiment.

As described above, although the preferred embodiments of the present disclosure have been described, those skilled in the art may implement the present disclosure by modifying the embodiments in various ways without departing from the spirit and scope of the present disclosure as set forth in the appended patent claims.

### EXPLANATION OF REFERENCE NUMERALS IN DRAWINGS

10: Metal body
20: Through hole
88: Micro-trench
100: Metal structure
200: Anodic oxide film
300: Photosensitive material
400: Seed layer
500: Mask

1. A method of manufacturing a metal structure, the method comprising:
preparing an anodic oxide film;
providing an anodic oxide film island by removing a peripheral portion of the anodic oxide film;
forming a metal body by forming a metal layer around the anodic oxide film island; and
forming a through hole in the metal body by removing the anodic oxide film island.

2. The method of claim 1, wherein the forming of the metal body uses a plating process.

3. The method of claim 1, wherein the forming of the metal body is a process of forming multiple metal layers made of different metals.

4. A method of manufacturing a metal structure, the method comprising:
preparing an anodic oxide film;
applying a photosensitive material to a surface of the anodic oxide film;
providing a photosensitive material island by removing a portion of the photosensitive material in a peripheral region;
providing an anodic oxide film island by removing the anodic oxide film in the peripheral region and not removing the anodic oxide film disposed under the photosensitive material island;
forming a metal body by forming a metal layer around the anodic oxide film island and the photosensitive material island; and
forming a through hole in the metal body by removing the anodic oxide film island and the photosensitive material island.

5. The method of claim 4, wherein the photosensitive material is a negative photoresist.

6-16. (canceled)
